(19) United States
(12) Patent Application Publication
(10) Pub. No.: US 2025/0046573 A1
(43) Pub. Date: Feb. 6, 2025

(54) PLASMA PROCESSING APPARATUS AND PLASMA PROCESSING METHOD

(71) Applicant: Tokyo Electron Limited, Tokyo (JP)

(72) Inventor: Mohd Fairuz BIN BUDIMAN, Miyagi (JP)

(73) Assignee: Tokyo Electron Limited, Tokyo (JP)

(21) Appl. No.: 18/922,549

(22) Filed: Oct. 22, 2024

Related U.S. Application Data
(63) Continuation of application No. PCT/JP2023/014711, filed on Apr. 11, 2023.

(30) Foreign Application Priority Data
Apr. 22, 2022 (JP) 2022-070814

(51) Int. Cl. H01J 37/32

(52) U.S. Cl. CPC H01J 37/32137; H01J 37/32642

(57) ABSTRACT

A plasma processing apparatus disclosed herein includes a chamber, a substrate support, one or more radio-frequency power supplies, and a correction power supply. The one or more radio-frequency power supplies supply one or more radio-frequency powers to the chamber in an ON period in which plasma is generated from a gas in the chamber. The correction power supply applies the negative voltage to the edge ring in one or more first periods in the ON period. Each of the one or more first periods corresponds to a plurality of times of a longest waveform cycle among waveform cycles of the one or more radio-frequency powers. The correction power supply stops the application of the negative voltage to the edge ring in a one or more second periods in the ON period. Each of the one or more second periods corresponds to the plurality of times of the longest waveform cycle.

### CROSS-REFERENCE TO RELATED APPLICATIONS

This application is a bypass continuation application of International Application No. PCT/JP2023/014711 having an international filing date of Apr. 11, 2023 and designating the United States, the International Application being based upon and claiming the benefit of priority from Japanese Patent Application No. 2022-070814, filed on Apr. 22, 2022, the entire contents of each are incorporated herein by reference.

### TECHNICAL FIELD

Embodiments of the present disclosure relate to a plasma processing apparatus and a plasma processing method.

### BACKGROUND

A plasma processing apparatus is used in plasma processing with respect to a substrate. The plasma processing apparatus includes a chamber and a substrate support. The substrate support is provided in the chamber. The substrate support supports the substrate placed on the substrate support. The substrate support further supports an edge ring (e.g., or a focus ring). The substrate is disposed in a region surrounded by the edge ring on the substrate support.

In the plasma processing apparatus, plasma is generated in the chamber by radio-frequency power being supplied from one or more radio-frequency power supplies. When plasma is generated, a sheath (e.g., plasma sheath) is formed between the plasma and the substrate and between the plasma and the edge ring. In order to make an ion from the plasma proceed vertically toward the entire surface of the substrate, it is necessary to eliminate a difference between a position of a boundary between the plasma and the sheath above the edge ring in a vertical direction and a position of a boundary between the plasma and the sheath above the substrate in the vertical direction. JP2019-186400A discloses a technique of controlling a voltage applied to the edge ring to reduce this difference.

### CITATION LIST

### Patent Documents

Patent Document 1: JP2019-186400A

### SUMMARY

The present disclosure provides a technique of correcting a traveling direction of an ion with respect to an edge of a substrate inward with respect to the substrate.

In an exemplary embodiment, a plasma processing apparatus is provided. The plasma processing apparatus includes a chamber, a substrate support, one or more radio-frequency power supplies, and a correction power supply. The substrate support is provided in the chamber, and configured to support an edge ring and a substrate placed on the substrate support, and the substrate is disposed in a region surrounded by the edge ring on the substrate support. The one or more radio-frequency power supplies include a radio-frequency power supply electrically connected to an electrode in the substrate support, and are electrically coupled to the chamber. The correction power supply is configured to apply a negative voltage to the edge ring. The one or more radio-frequency power supplies are configured to supply one or more radio-frequency powers in an ON period in which plasma is generated from a gas in the chamber. The correction power supply is configured to apply the negative voltage to the edge ring in one or more first periods in the ON period. Each of the one or more first periods corresponds to a plurality of times of the longest waveform cycle among waveform cycles of the one or more radio-frequency powers supplied from the one or more radio-frequency power supplies. The correction power supply is configured to stop the applying of the negative voltage to the edge ring in a one or more second periods in the ON period. Each of the one or more second periods corresponds to a plurality of times of the longest waveform cycle.

According to the present disclosure, it is possible to correct a traveling direction of an ion with respect to an edge of a substrate inward with respect to the substrate.

### BRIEF DESCRIPTION OF DRAWINGS

FIG. 1 is a view illustrating an example of a configuration of a plasma processing system.

FIG. 2 is a view illustrating an example of a configuration of a capacitively-coupled plasma processing apparatus.

FIG. 3 is an enlarged cross-sectional view of a part of the plasma processing apparatus according to one exemplary embodiment.

FIG. 4 is a timing chart related to an example of the plasma processing apparatus according to the one exemplary embodiment.

FIG. 5 is a timing chart related to another example of the plasma processing apparatus according to the one exemplary embodiment.

FIG. 6 is a view illustrating a relationship between a shape of a sheath and a traveling direction of an ion with respect to an edge of a substrate.

FIG. 7 is a flowchart of a control method according to the one exemplary embodiment.

FIG. 8 is a graph illustrating a result of a test.

### DETAILED DESCRIPTION

Hereinafter, various exemplary embodiments will be described in detail with reference to the drawings. Further, like reference numerals will be given to like or corresponding parts throughout the drawings.

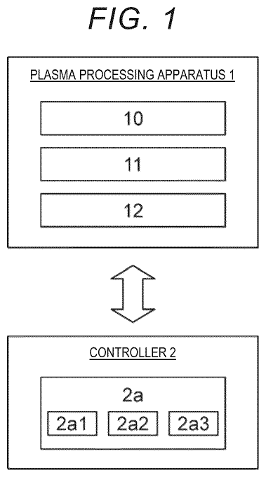

FIG. 1 is a diagram for explaining an example of a configuration of a plasma processing system. In an embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be Capacitively Coupled Plasma (CCP), Inductively Coupled Plasma (ICP), Electron-Cyclotron-Resonance Plasma (ECR plasma), Helicon Wave Plasma (HWP), Surface Wave Plasma (SWP), or the like.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

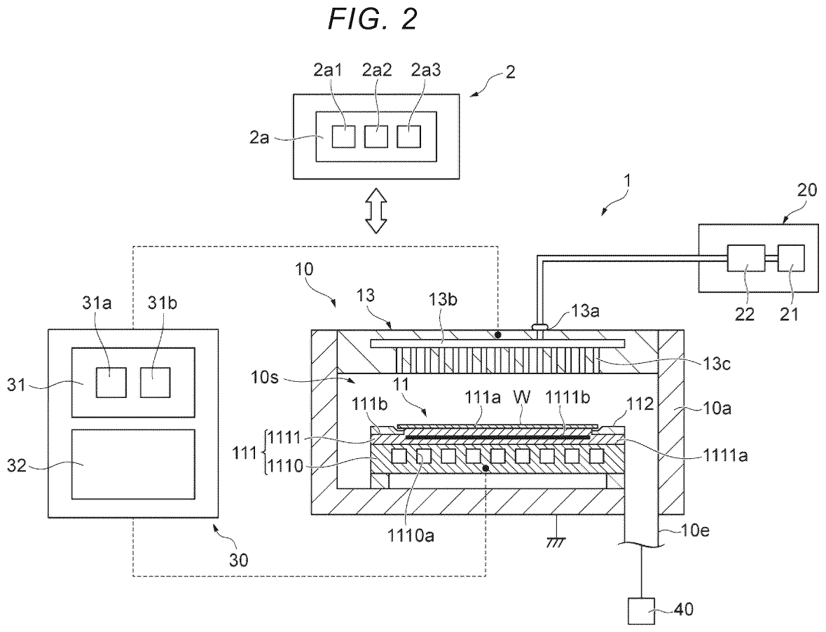

Hereinafter, a configuration example of a capacitively-coupled plasma processing apparatus as an example of the plasma processing apparatus 1 will be described. FIG. 2 is a view for explaining an example of a configuration of a capacitively-coupled plasma processing apparatus.

The capacitively-coupled plasma processing apparatus 1 includes the plasma processing chamber 10, the gas supply 20, a power source 30, and the exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The substrate support 11 is electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member.

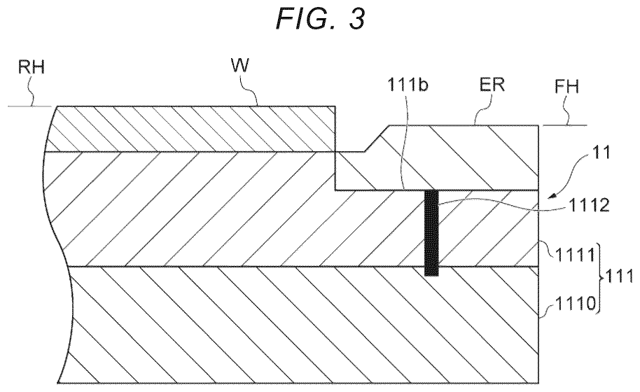

The ring assembly 112 includes one or more annular members. In one embodiment, the one or more annular members include an edge ring ER (see FIG. 3) and at least one cover ring. The edge ring ER is formed of a conductive material or an insulating material such as silicon or silicon carbide, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes at least one upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The power source 30 includes one or more radio-frequency power supplies 31 and a correction power supply 32. The one or more radio-frequency power supplies 31 are electrically coupled to the plasma processing chamber 10. The one or more radio-frequency power supplies 31 include a radio-frequency power supply electrically connected to an electrode inside the substrate support 11. In one embodiment, the one or more radio-frequency power supplies 31 include a source radio-frequency power supply 31a and a bias radio-frequency power supply 31b.

The source radio-frequency power supply 31a is electrically connected to a radio-frequency electrode. The source radio-frequency power supply 31a may be connected to the radio-frequency electrode through a matcher. The radio-frequency electrode may be an electrode of the substrate support 11 (for example, a conductive member of the base 1110 and/or one or more electrodes in the electrostatic chuck 1111) or an upper electrode. The source radio-frequency power supply 31a is configured to generate source radio-frequency power for generating plasma. The source radio-frequency power is a sinusoidal wave power having a waveform cycle, and is periodically generated. The waveform cycle of the source radio-frequency power has a time length that is a reciprocal number of a source frequency. The source frequency is, for example, a source frequency in a range of 10 MHz to 150 MHz. When the source radio-frequency power is supplied from the source radio-frequency power supply 31a to the radio-frequency electrode, plasma is generated from a gas in the plasma processing chamber 10.

The bias radio-frequency power supply 31b is electrically connected to a bias electrode of the substrate support 11. The bias radio-frequency power supply 31b may be connected to the bias electrode through a matcher. The bias electrode may be the conductive member of the base 1110 and/or one or more electrodes in the electrostatic chuck 1111. The bias electrode may be an electrode common to the radio-frequency electrode. The bias radio-frequency power supply 31b is configured to generate bias radio-frequency power. The bias radio-frequency power is a sinusoidal wave power having a waveform cycle, and is periodically generated. The waveform cycle of the bias radio-frequency power has a time length that is a reciprocal number of a bias frequency. The bias frequency is lower than the source frequency, and is, for example, a frequency in a range of 100 kHz to 60 MHz. The waveform cycle of the bias radio-frequency power is longer than the waveform cycle of the source radio-frequency power, and is the longest waveform cycle among the waveform cycles of the radio-frequency power used in the plasma processing apparatus 1. When the bias radio-frequency power is supplied from the bias radio-frequency power supply 31b to the bias electrode, an ion is attracted from the plasma into the substrate W.

In another embodiment, the plasma processing apparatus 1 may include a bias power supply that periodically applies a pulse of a voltage to the bias electrode, as electric bias energy, instead of the bias radio-frequency power supply 31b. The pulse of the voltage is periodically applied to the bias electrode in a time interval (e.g., waveform cycle) having a time length that is a reciprocal number of the bias frequency. A waveform of the pulse may be a rectangular wave, a triangular wave, or any waveform. A polarity of the voltage of the pulse is set such that the ion from the plasma can be attracted into the substrate W by generating a potential difference between the substrate W and the plasma. The pulse may be, for example, a pulse of a negative voltage.

The correction power supply 32 is configured to apply a negative voltage NV to the edge ring ER. The correction power supply 32 may be a direct-current power supply that generates a negative direct-current voltage as the negative voltage NV. Hereinafter, FIG. 3 will be referred to together with FIG. 2. FIG. 3 is an enlarged cross-sectional view of a part of the plasma processing apparatus according to one exemplary embodiment. As illustrated in FIGS. 2 and 3, the substrate support 11 supports the substrate W and the edge ring ER. The edge ring ER has a substantially annular shape. The substrate W is disposed on the substrate support 11 and in a region surrounded by the edge ring ER.

In one embodiment, the correction power supply 32 is electrically connected to the edge ring ER via a conductive member of the base 1110 and the conductor 1112. The conductor 1112 passes through the electrostatic chuck 1111. The conductor 1112 electrically connects the conductive member of the base 1110 and the edge ring ER to each other. The correction power supply 32 may be electrically connected to the edge ring ER via another electric path without the conductive member of the base 1110 and the conductor 1112.

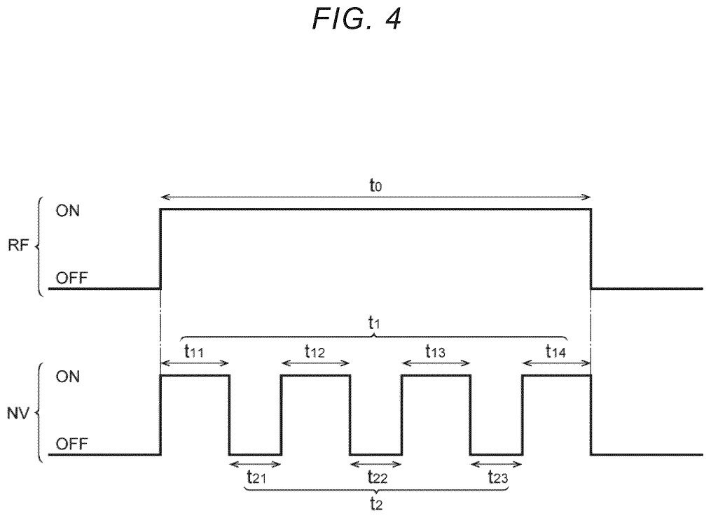

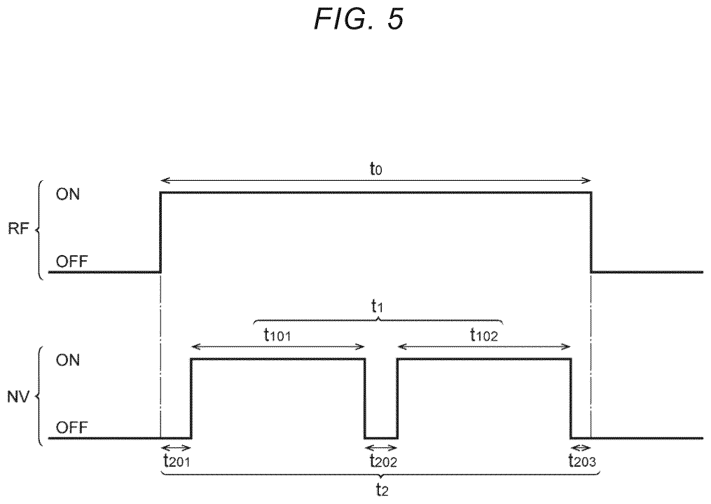

Hereinafter, FIGS. 4 and 5 will be referred to together with FIGS. 2 and 3. FIGS. 4 and 5 are timing charts of an example related to the plasma processing apparatus according to one exemplary embodiment. In each of FIGS. 4 and 5, ON of RF indicates that one or more radio-frequency powers are supplied from the one or more radio-frequency power supplies 31 to generate plasma in the plasma processing chamber 10. That is, in an ON period t₀, the one or more radio-frequency powers are supplied from the one or more radio-frequency power supplies 31 to generate plasma in the plasma processing chamber 10. In one embodiment, in the ON period t₀, source radio-frequency power and bias radio-frequency power are supplied as the one or more radio-frequency powers. In a period when the RF is OFF, the supply of the one or more radio-frequency powers from the one or more radio-frequency power supplies 31 is stopped.

The correction power supply 32 applies the negative voltage NV to the edge ring ER in one or more first periods t₁ within the ON period t₀. Each of the one or more first periods t₁ has a length corresponding to a plurality of times of the longest waveform cycle among waveform cycles of the one or more radio-frequency powers. The longest waveform cycle is, for example, a waveform cycle of the bias radio-frequency power. The correction power supply 32 stops the applying of the negative voltage NV to the edge ring ER in one or more second periods t₂ within the ON period t₀. Each of the one or more second periods t₂ has a length corresponding to a plurality of times of the longest waveform cycle. The length of each of the one or more first periods t₁ and the one or more second periods t₂ may be 0.1 seconds or more, 1 second or more, or 10 seconds or more. A length of the ON period t₀ may be 0.1 seconds or more, 1 second or more, or 10 seconds or more. The length of the ON period t₀ may be, for example, 100 seconds, or may be 100 seconds or less.

As illustrated in each of FIGS. 4 and 5, the ON period t₀ may include a plurality of first periods t₁ and a plurality of second periods t₂. In the example illustrated in FIG. 4, the ON period to includes first periods t₁₁, t₁₂, t₁₃, and t₁₄ as the plurality of first periods t₁, and includes second periods t₂₁, t₂₂, and t₂₃ as the plurality of second periods t₂. In the example illustrated in FIG. 5, the ON period t₀ includes first periods t₁₀₁ and t₁₀₂ as the plurality of first periods t₁, and includes second periods t₂₀₁, t₂₀₂, and t₂₀₃ as the plurality of second periods t₂. The plurality of first periods t₁ and the plurality of second periods t₂ alternately appear.

As illustrated in FIG. 4, a start timing of one first period t₁₁ may coincide with a start timing of the ON period t₀. That is, the applying of the negative voltage NV to the edge ring ER may be started at the start timing of the ON period t₀. Further, a timing for ending another first period t₁₄ may coincide with an end timing of the ON period t₀. That is, the applying of the negative voltage NV to the edge ring ER may be ended at the same time as the end timing when the ON period t₀.

As illustrated in FIG. 5, one second period t₂₀₁ may include the start timing of the ON period t₀. That is, the applying of the negative voltage NV to the edge ring ER may be started later than the start timing of the ON period t₀. Further, another second period t₂₀₃ may include the end timing of the ON period t₀. That is, the applying of the negative voltage NV to the edge ring ER may be ended before the end timing of the ON period t₀.

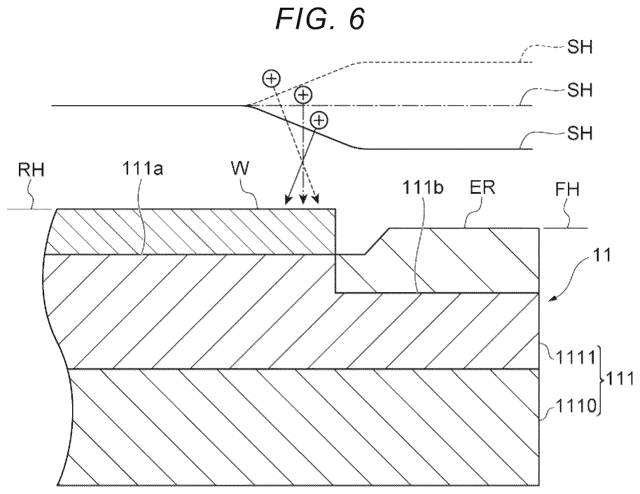

Hereinafter, FIG. 6 will be referred to. FIG. 6 is a view illustrating a relationship between a shape of a sheath and a traveling direction of an ion with respect to an edge of a substrate. In FIG. 6, a circular figure in which a letter [+] is described represents the ion. FIG. 6 illustrates a traveling direction of an ion with respect to a boundary SH between plasma and the sheath and an edge of the substrate W.

As illustrated by a solid line in FIG. 6, when a position of the boundary SH above the edge ring ER is lower than the position of the boundary SH above the substrate W, the traveling direction of the ion with respect to the edge of the substrate W has an inward inclination with respect to the substrate W as illustrated by a solid-line arrow. Such a traveling direction of the ion may occur in a case where a position FH of an upper surface of the edge ring ER is lower than a position of an upper surface of the substrate W, that is, a reference position RH. Such a traveling direction of the ion is corrected in a vertical direction as indicated by a one-dot chain line arrow by applying the negative voltage NV to the edge ring ER to eliminate a difference in height between the position of the boundary SH above the edge ring ER and the position of the boundary SH above the substrate W. That is, in a case where the traveling direction of the ion with respect to the edge of the substrate W is corrected outward with respect to the substrate W, the negative voltage NV is applied to the edge ring ER to raise the position of the boundary SH above the edge ring ER. For example, in a case where the traveling direction of the ion with respect to the edge of the substrate W is corrected outward with respect to the substrate W, the negative voltage NV is applied to the edge ring ER over the ON period t₀.

Meanwhile, the plasma processing apparatus 1 can apply the negative voltage NV to the edge ring ER only in the one or more first periods t₁ within the ON period t₀. When the negative voltage NV is applied to the edge ring ER only in the one or more first periods t₁, the traveling direction of the ion with respect to the edge of the substrate W is corrected inward with respect to the substrate W, as compared with a case where the negative voltage is applied to the edge ring ER over the ON period t₀. For example, according to the plasma processing apparatus 1, a traveling direction of an ion indicated by a broken line arrow in FIG. 6 can be corrected to be the traveling direction of the ion indicated by the one-dot chain line. Further, according to the plasma processing apparatus 1, the inward correction amount for the traveling direction of the ion with respect to the substrates W can be adjusted according to a ratio occupied by the one or more first periods t₁ within the ON period t₀. For example, in the plasma processing apparatus 1, the ratio occupied by the one or more first periods t₁ within the ON period t₀ may be adjusted within a range of 17% or more and 100% or less. Alternatively, for example, in the plasma processing apparatus 1, the ratio of the one or more first periods t₁ within the ON period t₀ may be adjusted within a range of 30% or more and 100% or less.

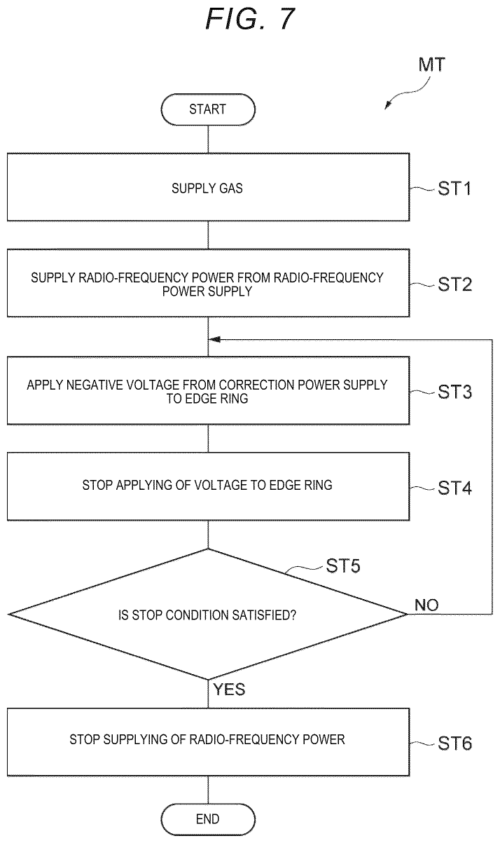

Hereinafter, a plasma processing method according to one exemplary embodiment will be described with reference to FIG. 7. FIG. 7 is a flowchart of a plasma processing method according to an exemplary embodiment. The plasma processing method illustrated in FIG. 7 (hereinafter, referred to as a “method MT”) includes steps ST1 to ST6. The method MT is performed in a state in which the substrate W is disposed on the substrate support 11 and in a region surrounded by the edge ring ER in the plasma processing chamber 10.

In the method MT, first, step ST1 and step ST2 are performed to generate plasma from a gas in the plasma processing chamber 10. In step ST1, a gas is supplied into the plasma processing chamber 10. The gas is supplied into the plasma processing chamber 10 by the gas supply 20. Further, the exhaust system 40 is controlled to set a pressure in the plasma processing chamber 10 to a designated pressure.

In step ST2, one or more radio-frequency powers are supplied from the one or more radio-frequency power supplies 31. The one or more radio-frequency powers are supplied in the ON period t₀. In one embodiment, the source radio-frequency power and the bias radio-frequency power described above are supplied as the one or more radio-frequency powers. Therefore, plasma is generated from the gas in the plasma processing chamber 10.

In the method MT, steps ST3 to ST5 are performed during execution of step ST1 and step ST2, that is, when plasma is being generated in the plasma processing chamber 10. In step ST3, the negative voltage NV is applied from the correction power supply 32 to the edge ring ER. The negative voltage NV is applied to the edge ring ER in each of the one or more first periods t₁ within the ON period t₀.

In the method MT, step ST4 is executed after step ST3 is executed. In step ST4, the applying of the negative voltage NV to the edge ring ER is stopped. The stopping of the applying of the negative voltage NV to the edge ring ER is performed in each of the one or more second periods t₂ within the ON period t₀.

In step ST5, it is determined whether a stop condition is satisfied. The stop condition is satisfied when a timing for shifting to step ST6 is reached. When the stop condition is not satisfied, the process from step ST3 is continued. Meanwhile, when the stop condition is satisfied, step ST6 is performed. In step ST6, the supply of the one or more radio-frequency powers from the one or more radio-frequency power supplies 31 is stopped. Therefore, the method MT is ended.

In the method MT, step ST4 may be performed before step ST3. Further, after step ST3 is performed after step ST4, step ST6 may be performed.

Although various exemplary embodiments have been described above, various additions, omissions, substitutions and changes may be made without being limited to the exemplary embodiments described above. In addition, other embodiments may be formed by combining elements in different embodiments.

Hereinafter, a test performed for the evaluation of the plasma processing apparatus 1 will be described. In the test, a plurality of sample substrates was prepared. Each of the plurality of sample substrates had a silicon oxide film and a mask. The mask was a photoresist mask having a pattern for forming a hole in the silicon oxide film. In the test, the silicon oxide films of a plurality of sample substrates were etched by using the capacitively-coupled plasma processing apparatus 1. For the etching of the silicon oxide film, a gas that included a fluorocarbon gas was supplied into the plasma processing chamber 10, and as one or more radio-frequency powers, source radio-frequency power and bias radio-frequency power are supplied over the ON period t₀. Further, in the etching of the silicon oxide films of the plurality of sample substrates, a ratio DR occupied by the one or more first periods t₁ in the ON period to was adjusted to 0%, 17%, 37%, 57%, 77%, and 97%, respectively.

In the test, an inclination angle θ of the hole formed in the silicon oxide film at each edge of each of the plurality of sample substrates was measured. The inclination angle θ is an amount that reflects a traveling direction of an ion with respect to an edge of the sample substrate. When the inclination angle θ is 90°, the traveling direction of the ion with respect to the edge of the sample substrate is vertical. In a case where the inclination angle θ is more than 90°, the traveling direction of the ion with respect to the edge of the sample substrate is inclined outward with respect to the sample substrate. In a case where the inclination angle θ is less than 90°, the traveling direction of the ion with respect to the edge of the sample substrate is inclined inward with respect to the sample substrate.

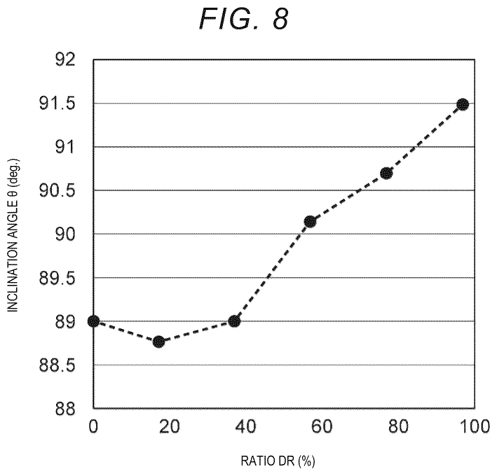

A result of the test is illustrated in FIG. 8. In a graph of FIG. 8, a horizontal axis represents the ratio DR, and a vertical axis represents the inclination angle θ. In a case where the ratio DR is 100%, that is, in a case where the negative voltage NV is applied to the edge ring ER over the ON period t₀, the inclination angle θ is more than 90°. That is, in a case where the negative voltage NV is applied to the edge ring ER over the ON period t₀, the traveling direction of the ion with respect to the edge of the sample substrate is inclined outward with respect to the sample substrate. Further, in a case where the ratio DR is less than 100%, the inclination angle θ is less than the inclination angle θ in a case where the ratio DR is 100%. That is, in a case where the ON period t₀ includes the one or more first periods t₁ and the one or more second periods t₂, the inclination angle θ is less than the inclination angle in a case where the negative voltage NV is applied to the edge ring ER over the ON period t₀. Therefore, it has been confirmed that in a case where the ON period t₀ includes the one or more first periods t₁ and the one or more second periods t₂, the traveling direction of the ion with respect to the edge of the sample substrate is corrected inward with respect to the sample substrate. Further, the inclination angle θ is decreased according to the decrease of the ratio DR from 100% to 17% or 30%. From this fact, it has been confirmed that it is possible to adjust the inward correction amount for the traveling direction of the ion with respect to the edge of the sample substrate, according to the ratio DR.

Hereinafter, various exemplary embodiments included in the present disclosure will be described in the following [E1] to [E11].

### [E1]

A plasma processing apparatus including: a chamber; a substrate support disposed in the chamber, and configured to support an edge ring and a substrate placed on the substrate support, the substrate being disposed in a region surrounded by the edge ring on the substrate support; one or more radio-frequency power supplies that include a radio-frequency power supply electrically connected to an electrode in the substrate support, and are electrically coupled to the chamber; and a correction power supply configured to apply a negative voltage to the edge ring, in which the one or more radio-frequency power supplies are configured to supply one or more radio-frequency powers in an ON period in which plasma is generated from a gas in the chamber, and the correction power supply is configured to apply the negative voltage to the edge ring in one or more first periods in the ON period, each of the one or more first periods corresponding to a plurality of times of a longest waveform cycle among waveform cycles of the one or more radio-frequency powers supplied from the one or more radio-frequency power supplies, and stop the applying of the negative voltage to the edge ring in one or more second periods in the ON period, each of the one or more second periods corresponding to a plurality of times of the longest waveform cycle.

In an embodiment of E1, a traveling direction of an ion with respect to an edge of the substrate can be corrected inward with respect to the substrate, as compared with the traveling direction of the ion with respect to the edge of the substrate in a case where the negative voltage is applied to the edge ring over the ON period. Further, according to the embodiment, it is possible to adjust the inward correction amount for the traveling direction of the ion with respect to the substrate, according to a ratio occupied by the one or more first periods in the ON period.

### [E2]

The plasma processing apparatus according to E1, in which each of the one or more first periods and the one or more second periods is 0.1 seconds or more.

### [E3]

The plasma processing apparatus according to E1, in which each of the one or more first periods and the one or more second periods is 1 second or more.

### [E4]

The plasma processing apparatus according to E1, in which each of the one or more first periods and the one or more second periods is 10 seconds or more.

### [E5]

The plasma processing apparatus according to any one of E1 to E4, in which one of the one or more second periods includes a start time point of the ON period.

### [E6]

The plasma processing apparatus according to E5, in which the ON period includes a plurality of second periods as the one or more second periods, and one of the plurality of second periods includes an end time point of the ON period.

### [E7]

The plasma processing apparatus according to any one of E1 to E4, in which the ON period includes a plurality of first periods as the one or more first periods and includes a plurality of second periods as the one or more second periods, and the plurality of first periods and the plurality of second periods alternately appear. The plurality of first periods and the plurality of second periods can alternate at regular or irregular intervals.

### [E8]

The plasma processing apparatus according to any one of E1 to E7, in which the correction power supply is a direct-current power supply that generates a negative direct-current voltage as the negative voltage.

### [E9]

The plasma processing apparatus according to any one of E1 to E8, in which a source radio-frequency power supply and a bias radio-frequency power supply are provided as the one or more radio-frequency power supplies, the source radio-frequency power supply is a source radio-frequency power supply that generates source radio-frequency power for plasma generation, and the bias radio-frequency power supply is the radio-frequency power supply electrically connected to the electrode of the substrate support, and configured to generate bias radio-frequency power.

### [E10]

The plasma processing apparatus according to E9, in which the longest waveform cycle is a waveform cycle of the bias radio-frequency power.

### [E11]

A plasma processing method performed by a plasma processing apparatus, the method including: (a) supplying one or more radio-frequency powers from one or more radio-frequency power supplies electrically coupled to a chamber of the plasma processing apparatus, in an ON period in which plasma is generated from a gas in the chamber, the one or more radio-frequency power supplies including a radio-frequency power supply electrically connected to an electrode in a substrate support provided in the chamber, the substrate support supporting an edge ring disposed to surround a substrate placed on the substrate support; (b) applying a negative voltage from a correction power supply to the edge ring in one or more first periods in the ON period, each of the one or more first periods corresponding to a plurality of times of a longest waveform cycle among waveform cycles of the one or more radio-frequency powers supplied from the one or more radio-frequency power supplies; and (c) stopping the applying of the negative voltage to the edge ring in one or more second periods in the ON period, each of the one or more second periods corresponding to a plurality of times of the longest waveform cycle.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A plasma processing apparatus comprising:
a chamber;
a substrate support disposed in the chamber, and configured to support an edge ring and a substrate placed on a region of the substrate support surrounded by the edge ring;
one or more radio-frequency power supplies that include a radio-frequency power supply electrically connected to an electrode in the substrate support, and the one or more radio-frequency power supplies are electrically coupled to the chamber; and
a correction power supply configured to apply a negative voltage to the edge ring,
wherein the one or more radio-frequency
power supplies are configured to supply one or more radio-frequency powers in an ON period in which plasma is generated from a gas in the chamber, and
the correction power supply is configured to
apply the negative voltage to the edge ring in one or more first periods in the ON period, each of the one or more first periods corresponding to a plurality of times of a longest waveform cycle among waveform cycles of the one or more radio-frequency powers supplied from the one or more radio-frequency power supplies, and
stop the applying of the negative voltage to the edge ring in one or more second periods in the ON period, each of the one or more second periods corresponding to a plurality of times of the longest waveform cycle.

2. The plasma processing apparatus according to claim 1,
wherein each of the one or more first periods and the one or more second periods is 0.1 seconds or more.

3. The plasma processing apparatus according to claim 1,
wherein each of the one or more first periods and the one or more second periods is 1 second or more.

4. The plasma processing apparatus according to claim 1,
wherein each of the one or more first periods and the one or more second periods is 10 seconds or more.

5. The plasma processing apparatus according to claim 1,
wherein one of the one or more second periods includes a start time point of the ON period.

6. The plasma processing apparatus according to claim 5,
wherein the one or more second periods in the ON period includes a plurality of second periods, and one of the plurality of second periods includes an end time point of the ON period.

7. The plasma processing apparatus according to claim 1,
wherein the one or more first periods in the ON period includes a plurality of first periods, and
the one or more second periods in the ON period includes a plurality of second periods, and the plurality of first periods and the plurality of second periods alternate.

8. The plasma processing apparatus according to claim 1,
wherein the correction power supply is a direct-current power supply that generates a negative direct-current voltage as the negative voltage.

9. The plasma processing apparatus according to claim 1,
wherein the one or more radio-frequency power supplies includes a source radio-frequency power supply and a bias radio-frequency power supply,
the source radio-frequency power supply is a source radio-frequency power supply that generates source radio-frequency power for plasma generation, and
the bias radio-frequency power supply is the radio-frequency power supply electrically connected to the electrode of the substrate support, and configured to generate bias radio-frequency power.

10. The plasma processing apparatus according to claim 9,
wherein the longest waveform cycle is a waveform cycle of the bias radio-frequency power.

11. A plasma processing method performed by a plasma processing apparatus, the method comprising:
(a) supplying one or more radio-frequency powers from one or more radio-frequency power supplies electrically coupled to a chamber of the plasma processing apparatus, the supplying the one or more radio-frequency powers is performed during an ON period in which plasma is generated from a gas in the chamber, the one or more radio-frequency power supplies including a radio-frequency power supply electrically connected to an electrode in a substrate support provided in the chamber, the substrate support supporting an edge ring that surrounds a substrate placed on the substrate support;
(b) applying a negative voltage from a correction power supply to the edge ring in one or more first periods in the ON period, each of the one or more first periods corresponding to a plurality of times of a longest waveform cycle among waveform cycles of the one or more radio-frequency powers supplied from the one or more radio-frequency power supplies; and
(c) stopping the applying of the negative voltage to the edge ring in one or more second periods in the ON period, each of the one or more second periods corresponding to a plurality of times of the longest waveform cycle.

12. The plasma processing method according to claim 11,
wherein each of the one or more first periods and the one or more second periods is 0.1 seconds or more.

13. The plasma processing method according to claim 11,
wherein each of the one or more first periods and the one or more second periods is 1 second or more.

14. The plasma processing method according to claim 11,
wherein each of the one or more first periods and the one or more second periods is 10 seconds or more.

15. The plasma processing method according to claim 11,
wherein one of the one or more second periods includes a start time point of the ON period.

16. The plasma processing method according to claim 15,
wherein the one or more second periods in the ON period includes a plurality of second periods, and one of the plurality of second periods includes an end time point of the ON period.

17. The plasma processing method according to claim 11,
wherein the one or more first periods in the ON period includes a plurality of first periods, and
the one or more second periods in the ON period includes a plurality of second periods, and the plurality of first periods and the plurality of second periods alternate.

18. The plasma processing method according to claim 11,
wherein the correction power supply is a direct-current power supply that generates a negative direct-current voltage as the negative voltage.

19. The plasma processing method according to claim 11,
wherein the one or more radio-frequency power supplies includes a source radio-frequency power supply and a bias radio-frequency power supply,
the source radio-frequency power supply is a source radio-frequency power supply that generates source radio-frequency power for plasma generation, and
the bias radio-frequency power supply is the radio-frequency power supply electrically connected to the electrode of the substrate support, and configured to generate bias radio-frequency power.

20. The plasma processing method according to claim 19,
wherein the longest waveform cycle is a waveform cycle of the bias radio-frequency power.
